(19) United States
(12) Patent Application Publication
(10) Pub. No.: US 2006/0001058 A1
(43) Pub. Date: Jan. 5, 2006

(54) Fin field effect transistor memory cell

(75) Inventors: Lars Dreeskornfeld, Neubiberg (DE); Jessica Hartwich, Neubiberg (DE); Franz Hofmann, Munich (DE); Johannes Kretz, Munchen (DE); Michael Specht, Munich (DE)

Correspondence Address: DARBY & DARBY P.C., P. O. BOX 5257, NEW YORK, NY, 10150-5257, US

(73) Assignee: Infineon Technologies AG, Munich (DE)

(21) Appl. No.: 11/157,496

(22) Filed: Jun. 20, 2005

Related U.S. Application Data
(63) Continuation of application No. PCT/EP03/14473, filed on Dec. 18, 2003.

(30) Foreign Application Priority Data
Dec. 20, 2002 (DE) 102 60 334.0

(51) Int. Cl. H01L 29/76; H01L 21/336

(52) U.S. Cl. 257/288; 257/368; 438/288; 438/292

(57) ABSTRACT

A fin field effect transistor memory cell having a first and a second source/drain region, a gate region, a semiconductor fin having a channel region between the first and the second source/drain region, a charge storage layer configured as a trapping layer arranged at least partly on the gate region, and a word line region on at least one part of the charge storage layer. The charge storage layer is set up such that electrical charge carriers can be selectively introduced into the charge storage layer or be removed therefrom by applying predetermined electrical potentials to the fin field effect transistor memory cell.

### CROSS-REFERENCE TO RELATED APPLICATION

This application is a continuation of International Patent Application Serial No. PCT/EP2003/014473, filed Dec. 18, 2003, which published in German on Jul. 15, 2004 as WO 2004/059738, and is incorporated herein by reference in its entirety.

### FIELD OF THE INVENTION

The invention relates to a fin field effect transistor memory cell, a fin field effect transistor memory cell arrangement, and a method for the production of a fin field effect transistor memory cell.

### BACKGROUND OF THE INVENTION

In view of the rapid development in computer technology, there is a need for high-density, low-power and nonvolatile memories, in particular for mobile applications in the area of data storage.

The prior art discloses a floating gate memory, in which an electrically conductive floating gate region is arranged above a gate insulating layer of a field effect transistor integrated in a substrate, into which floating gate region electrical charge carriers can be permanently introduced by means of Fowler-Nordheim tunneling. On account of the field effect, the value of the threshold voltage of such a transistor is dependent on whether or not charge carriers are stored in the floating gate. Consequently, an item of memory information can be coded in the presence or absence of electrical charge carriers in the floating gate layer.

However, introducing electrical charge carriers into a floating gate requires a high voltage of typically 15V to 20V. This may lead to damage to sensitive integrated components and is unattractive, moreover, for energy-saving (e.g. low-power applications) or mobile applications (e.g. mobile radio telephones, personal digital assistant, PDA). Furthermore, the write times in the case of Fowler-Nordheim tunneling are typically in the milliseconds range and are thus too long to meet the requirements of modern memories.

In the case of NROM memory (“nitrided read only memory”), a silicon nitride trapping layer is used as gate insulating layer of a field effect transistor, it being possible for charge carriers to be permanently introduced into the silicon nitride layer as charge storage layer by means of channel hot electron injection. Typical programming voltages are approximately 9V in this case, and write times of 150 ns are achieved at an individual cell.

Eitan, B., Pavan, P., Bloom, I., Aloni, E., Frommer, A., Finzi, D. (2000) “NROM: A Novel Localized Trapping, 2-Bit Nonvolatile Memory Cell” IEEE Electron Device Letters 21(11): 543 545, discloses an NROM memory cell in which two bits of memory information can be stored in one transistor.

An NROM memory cell has the disadvantage of a high power consumption, however. Furthermore, the scalability of NROM memory cells is poor on account of short channel effects, such as the “punch through” effect, which occurs in particular at a channel length of typically less than 200 nm. Moreover, the read current is very small in the case of a small width of transistors of NROM memory cells. This is also an obstacle to continued scaling.

Tomiye, H., Terano, T., Nomoto, K., Kobayashi, T. (2002) “A novel 2-bit/cell MONOS memory device with a wrapped-control-gate structure that applies source-side hot-electron injection” VLSI 2002 Symposium, pp. 206 207, discloses a MONOS memory cell, in which a control gate is provided separately from a word line. Information is stored in accordance with Tomiye, H. et al. by means of source-side injection of charge carriers into an ONO charge storage layer (silicon oxide/silicon nitride/silicon oxide). This lowers the power consumption in comparison with a conventional NROM memory cell.

However, the memory cell disclosed in Tomiye, H. et al. also has the problem of poor scalability and a small read current particularly in the case of a small transistor width.

To summarize, a floating gate memory cell has the disadvantage of a high voltage and an insufficiently rapid serial access to the individual memory cell. A split gate cell has the disadvantage of poor scalability and a moderate storage density per bit. Disadvantages of the memory cell which is based on source-side injection of charge carriers and are disclosed in Tomiye, H. et al. are the poor scalability below a channel length of 200 nm and a small read current in the case of a small transistor width.

### SUMMARY OF THE INVENTION

The invention is based on the problem, in particular, of specifying a memory cell, a memory cell arrangement and a method for the production of a memory cell in the case of which low-power programming, a high storage density and good scalability are realized.

The problem is solved by means of a fin field effect transistor memory cell, by means of a fin field effect transistor memory cell arrangement and by means of a method for the production of a fin field effect transistor memory cell.

The fin field effect transistor memory cell according to the invention contains a first and a second source/drain region, a gate region and a semiconductor fin having a channel region between the first and the second source/drain region. The fin field effect transistor memory cell furthermore contains a charge storage layer arranged at least partly on the gate region, and a word line region on at least one part of the charge storage layer. The charge storage layer is set up such that electrical charge carriers can be selectively introduced into the charge storage layer or be removed therefrom by means of applying predetermined electrical potentials to the fin field effect transistor memory cell.

Furthermore, a method for the production of a fin field effect transistor memory cell is provided, in which a first and a second source/drain region are formed, a gate region is formed and a semiconductor fin having a channel region is formed between the first and the second source/drain region. Furthermore, a charge storage layer is formed, which is arranged at least partly on the gate region. A word line region is formed on at least one part of the charge storage layer. The charge storage layer is set up such that electrical charge carriers can be selectively introduced into the charge storage layer or be removed therefrom by means of applying predetermined electrical potentials to the fin field effect transistor memory cell.

### BRIEF DESCRIPTION OF THE DRAWINGS

Exemplary embodiments of the invention are illustrated in the figures and are explained in more detail below.

In figures:

FIG. 1 shows a schematic arrangement on the basis of which the principle of source-side programming is described;

FIG. 2 shows a perspective view of fin field effect transistor memory cell in accordance with a preferred exemplary embodiment of the invention;

FIG. 3 shows a layout view of a fin field effect transistor memory cell arrangement in accordance with a preferred exemplary embodiment of the invention;

FIG. 4 shows a first cross-sectional view of the memory cell arrangement shown in FIG. 3, taken along a section line I-I′ from FIG. 3;

FIG. 5 shows a second cross-sectional view of the memory cell arrangement shown in FIG. 3, taken along a section line II-II′ from FIG. 3; and

FIGS. 6A to 6F show cross-sectional views of layer sequences at different points in time during a method for the production of a fin field effect transistor memory cell arrangement in accordance with a preferred exemplary embodiment of the invention.

### DETAILED DESCRIPTION OF PREFERRED EMBODIMENTS OF THE INVENTION

The fin field effect transistor memory cell according to the invention contains a first and a second source/drain region, a gate region and a semiconductor fin having a channel region between the first and the second source/drain region. The fin field effect transistor memory cell furthermore contains a charge storage layer arranged at least partly on the gate region, and a word line region on at least one part of the charge storage layer. The charge storage layer is set up such that electrical charge carriers can be selectively introduced into the charge storage layer or be removed therefrom by means of applying predetermined electrical potentials to the fin field effect transistor memory cell.

Furthermore, a method for the production of a fin field effect transistor memory cell is provided, in which a first and a second source/drain region are formed, a gate region is formed and a semiconductor fin having a channel region is formed between the first and the second source/drain region. Furthermore, a charge storage layer is formed, which is arranged at least partly on the gate region. A word line region is formed on at least one part of the charge storage layer. The charge storage layer is set up such that electrical charge carriers can be selectively introduced into the charge storage layer or be removed therefrom by means of applying predetermined electrical potentials to the fin field effect transistor memory cell.

One basic idea of the invention is to be seen in the fact that a memory cell based on a fin field effect transistor (also referred to hereinafter as fin-FET) is provided in which a charge storage layer is arranged between a gate region and a word line region arranged thereon. In the case of such a fin-FET arrangement, charge storage layer regions arranged at one or more side areas of the gate region, by way of example, may be programmed with low power using a source-side (or drain-side) injection. The charge storage layer may be realized for example as an ONO layer sequence (silicon oxide/silicon nitride/silicon oxide). Electrical charge carriers can be permanently stored in such a charge storage layer and significantly influence the conductivity of a channel region realized by means of a semiconductor fin, wherein the memory information can be coded.

In the case of the arrangement according to the invention, apart from the gate region, a word line region that is generally electrically decoupled therefrom is formed, in which case the arrangement may be referred to as a split gate arrangement. The memory cell according to the invention enables lower-power programming.

Furthermore, the memory cell according to the invention has a high storage density of two bits. A first bit may be stored in the charge storage layer in a boundary region between the first source/drain region and the word line region, in the form of charge carriers introduced there. A second bit may be stored in the charge storage layer in a boundary region between the second source/drain region and the word line region, in the form of charge carriers introduced there. A high storage density and a low cost expenditure per bit are thus made possible.

The invention provides a memory cell which, on account of the double gate effect of a fin field effect transistor, enables better scalability of the channel length than in the case of a purely planar geometry as in Eitan, B. et al., for example. The memory cell according to the invention has a high storage density of typically 2F2 to 4F2, where F is the minimum feature size that can be achieved in a technology generation.

Furthermore, in the design and production of the fin field effect transistor memory cell according to the invention, the height of the fin made of semiconductor material may be set such that a desired read current can be achieved. The height of the fin is thus a degree of freedom in the configuration of the memory cell which can be used to set the read and programming properties.

Consequently, one important aspect of the invention consists in combining, in a fin-FET memory cell arrangement, low-power programming by means of source-side injection of charge carriers with a high storage density, with a high read current, low costs per bit and better scalability than in the case of an NROM memory cell or floating gate memory cell.

The fin field effect transistor memory cell according to the invention combines the advantages of “source-side injection” programming with the advantages of a double gate arrangement using a fin-FET and can thus be scaled better. Furthermore, a further advantage is to be seen in the compatibility of the memory cell with logic components with fin-FET geometry.

In the case of the memory cell according to the invention, the word line region may be divided into a first word line partial region and into a second word line partial region such that electrical charge carriers can in each case be introduced into a boundary region between the first word line partial region and the charge storage layer and into a boundary region between the second word line partial region and the charge storage layer or be removed there from. The division of the word line region into two word line partial regions (which are either electrically decoupled from one another or coupled to one another) may be realized such that two word lines that essentially run parallel to one another along the side areas of the fin-FET transistors are provided.

The first and second word line partial regions may be arranged at two opposite lateral sections of the gate region (control gate region).

The charge storage layer may have or comprise a silicon oxide/silicon nitride/silicon oxide layer sequence (ONO layer sequence), aluminum oxide (Al₂O₃), yttrium oxide (Y₂O₃), lanthanum oxide (LaO₂), hafnium oxide (HfO₂), zirconium oxide (ZrO₂), amorphous silicon, tantalum oxide (Ta₂O₅), titanium oxide (TiO₂) and/or an aluminate. One example of an aluminate is an alloy comprising the components aluminum, zirconium and oxygen (AlZrO). A charge storage layer realized as an ONO layer sequence has three partial layers which may in each case have a thickness of 5 nm.

In particular, the charge storage layer may clearly be dimensioned or set up in a DRAM-suitable manner (“dynamic random access memory”), i.e. it is possible to achieve programming times of 10 ns or less. The partial layers of the charge storage layer are to be provided such that they are sufficiently thin for this purpose. By way of example, in this case, the charge storage layer may be formed from a tunnel dielectric, a storage dielectric and a blocking dielectric. The tunnel dielectric may have a thickness of typically 1 nm to 3 nm and may be formed from silicon oxide, by way of example. The storage dielectric may have a thickness of typically 2 nm to 4 nm and may be formed for example from amorphous silicon or from a high-k material with a sufficiently low barrier height (e.g. Ta2O5 or TiO2). The blocking dielectric may have a thickness of typically 2 nm and may be formed for example from silicon oxide or a high-k material.

Consequently, a sufficiently thin charge storage layer (or sufficiently thin partial layers of the charge storage layer) is to be used for a sufficiently short write time of 10 ns. If a particularly high retention time (typically ten years) is striven for, then the charge storage layer is to be provided such that it is sufficiently thick.

The gate region of the memory cell may surround the semiconductor fin in an essentially U-shaped manner. This configuration provides a double gate enabling a particularly exact control of the conductivity of the channel region of the memory cell.

The height of the semiconductor fin is preferably set in such a way as to achieve a predetermined value for a read current for reading out information stored in the memory cell.

The memory cell may have a first bit line region coupled to the first source/drain region and a second bit line region coupled to the second source/drain region.

The source/drain regions may be doped sections of the semiconductor fin or may be realized as part of the bit line regions.

Furthermore, the memory cell may be set up such that, by means of applying predetermined electrical potentials to the gate region, to the word line region and/or to at least one bit line region, charge carriers can selectively be introduced into the charge storage layer by means of injection of hot charge carriers or be removed there from.

The fin field effect transistor memory cell arrangement according to the invention, having fin field effect transistor memory cells according to the invention, is described in more detail below. Refinements of the memory cell also apply to the memory cell arrangement.

The fin field effect transistor memory cells of the memory cell arrangement may be arranged essentially in matrix-type fashion.

The memory cell arrangement may have a common word line region for memory cells arranged along a first direction. By way of example, a row or column of memory cells may have one or more common word lines.

Furthermore, the memory cell arrangement may have common bit line regions for memory cells arranged along a second direction. By way of example, a column or row of memory cells may have one or more common bit lines.

The first and second directions are preferably oriented essentially orthogonally with respect to one another.

In the case of the memory cell arrangement, the lateral extent of a word line region may be different (in particular smaller) in a section in which it crosses a gate region than in a section free of a crossing with a gate region.

Similar or identical components in different figures are provided with the same reference numerals.

The illustrations in the figures are schematic and not to scale.

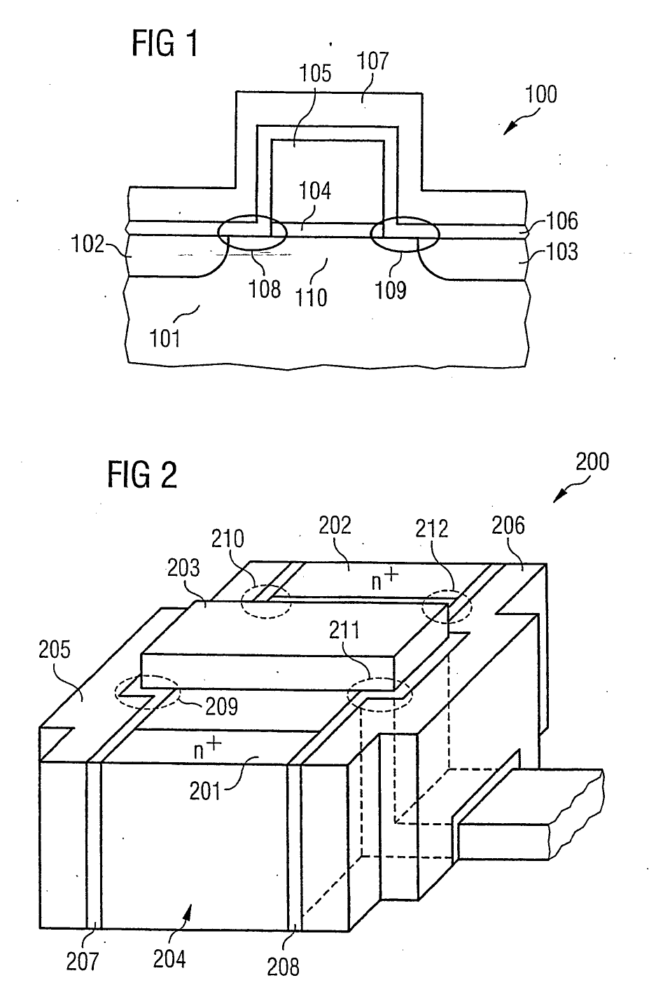

A description is given below, referring to FIG. 1, of the source-side (or drain-side) injection of charge carriers with a gate that is divided into a control gate and into a word line that is electrically decoupled from the latter. The memory cell according to the invention can be programmed or read by means of the programming scheme described below.

FIG. 1 shows a memory cell 100, which is formed on and in a silicon substrate 101. A gate dielectric 104 is provided on the silicon substrate 101 between a first and a second bit line 102, 103. A control gate 105 is arranged on the gate dielectric 104. An ONO layer sequence 106 is formed as a charge storage layer on this layer sequence. A word line 107 is formed on the ONO layer sequence 106, which word line 107 extends across the bit lines 102, 103 and is electrically decoupled from the bit lines 102, 103 by means of the ONO layer sequence 106. Furthermore, FIG. 1 shows a first charge storage region 108 of the charge storage layer 106 in a boundary region between first bit line 102, control gate 105 and word line 107, and a second charge storage region 109 of the charge storage layer 106 in a boundary region between second bit line 103, control gate 105 and word line 107.

A description is given below of what electrical potentials are applied to the terminals of the memory cell 100 in order to introduce electrical charge carriers into the charge storage regions 108, 109 and thus to program an item of memory information.

In order to introduce electrical charge carriers into the first charge storage region 108, the word line 107 is brought to an electrical potential of 9V, by way of example. The first bit line 102 is brought to a potential of 5V, by way of example, whereas the second bit line 103 is brought to an electrical potential of 0V. In order to enable a “source-side” injection of hot electrons (“source-side hot-electron injection”, SSHE), the control gate 105 is brought to a potential of approximately 1V (close to the threshold voltage of the field effect transistor-like arrangement 100). In order to suppress the injection of charge carriers, by contrast, the control gate 105 is brought to an electrical potential of 0V. In this way, electrical charge carriers can be introduced permanently into the first charge storage region 108. In order to introduce charge carriers into the second charge storage region 109, the electrical potentials of the bit lines 102, 103 can simply be interchanged. It should be noted that the charge storage regions 108, 109 have been inserted into the figure purely schematically for the purpose of a clear elucidation. In actual fact, these regions may be spatially extended to a greater or weaker extent than is shown in the figure or may be localized at a somewhat different location in the charge storage layer.

In order to read out information contained in the charge storage regions 108 and 109, respectively, the control gate 105 is brought to an electrical potential of approximately 1.5V and a voltage of 1.5V is applied between the bit lines 102, 103. In this operating state, the word line 107 may be brought to an electrical potential of approximately 1.5V to 3V, in order to obtain inversion. The value of the electric current flowing through the channel region 110 then depends on whether or not electrical charge carriers are contained in the first charge storage region 108 and/or in the second charge storage region 109 since charge carriers introduced into one of the charge storage regions 108, 109 clearly have a similar influence on the electrical conductivity of the channel region 110 to a voltage applied to the control gate 105. The stored memory information is coded in the value of the electric current determined.

In order to erase information from one of the charge storage regions 108, 109 of the memory cell 100, the control gate 105 is brought to an electrical potential of 5V, by way of example. In order to erase information from the first charge storage region 108, the first bit line 102 is brought to an electrical potential of 0V, by way of example, whereas the second bit line 103 is brought to an electrical potential of 7V. In order to erase the information in the second charge storage region 109, the potentials on the bit lines 102, 103 may simply be interchanged.

A description is given below, referring to FIG. 2, of a fin field effect transistor memory cell 200 in accordance with a preferred exemplary embodiment of the invention.

The fin-FET memory cell 200 has a first source/drain region 201 and a second source/drain region 202. A channel region is arranged between the two source/drain regions 201, 202, the channel region and the two source/drain regions 202, 201 being components of a silicon fin 204. The two source/drain regions 201, 202 are realized as two regions of the silicon fin 204 that are separated from one another by means of the channel region, the source/drain regions being formed by means of implantation of n₊-type doping atoms (for example arsenic) into regions of the silicon fin 204. A control gate 203 is formed on the channel region in a U-shaped manner, a thin gate insulating layer (not shown in FIG. 2) being formed between the channel region and the control gate 203. Furthermore, in FIG. 2 a first ONO region 207 (silicon oxide/silicon nitride/silicon oxide layer sequence) is formed, and a second ONO region 208 is formed. The ONO regions 207, 208 are formed on opposite side areas of the silicon fin 204 and of the control gate 203. The ONO regions 207, 208 are set up such that electrical charge carriers can selectively be introduced into them by means of applying predetermined electrical potentials to the terminals of the fin-FET memory cell 200 or be removed there from, an item of memory information being coded in charge carriers introduced possibly into one or both of the ONO regions 207, 208. Furthermore, a first word line 205 is applied laterally on the first ONO region 207. Furthermore, a second word line 206 is applied laterally on the second ONO region 208.

FIG. 2 schematically illustrates first to fourth charge storage regions 209 to 212, which are partial regions of the first and second ONO regions 207, 208, and into which charge storage regions 209 to 212 electrical charge carriers can be introduced by means of source-side (or drain-side) injection of charge carriers or holes (cf. FIG. 1 and associated description).

In order to introduce electrical charge carriers in the first charge storage region 209, by way of example, the first word line 205 is brought to an electrical potential of 9V, whereas a first bit line adjoining the first source/drain region 201 is brought to a potential of 5V. A second bit line adjoining the second source/drain region 202 is brought to a potential of 0V. In order to enable electrical charge carriers to be introduced into the first charge storage region 209, the control gate 203 is brought to a potential of 1V. At a potential of 0V at the control gate 203, by contrast, an introduction of electrical charge carriers into the first charge storage region 209 is avoided. Charge carriers can be introduced into each of the charge storage regions 209 to 212 in a corresponding manner, whereby memory information can be programmed in charge storage regions 209 to 212. Said information can be read out by applying a predetermined electrical voltage of 1.5V, by way of example, between the source/drain regions 201, 202, and furthermore bringing the control gate 203 to a predetermined electrical potential of 1.5V, by way of example. Furthermore, in order to read out an item of information in the first charge storage region 209, the first word line 205 is brought to an electrical potential of approximately 1.5V to 3V. On account of the field effect in the channel region between the source/drain regions 201, 202, the value of the current flow between the source/drain regions 201, 202 is dependent on whether or not electrical charge carriers are introduced in the respective charge storage regions 209 to 212. Consequently, the memory information contained in the storage regions 209 to 212 is contained in the value of the current flow (or in a characteristic alteration of the value of the threshold voltage of the fin-FET arrangement 200).

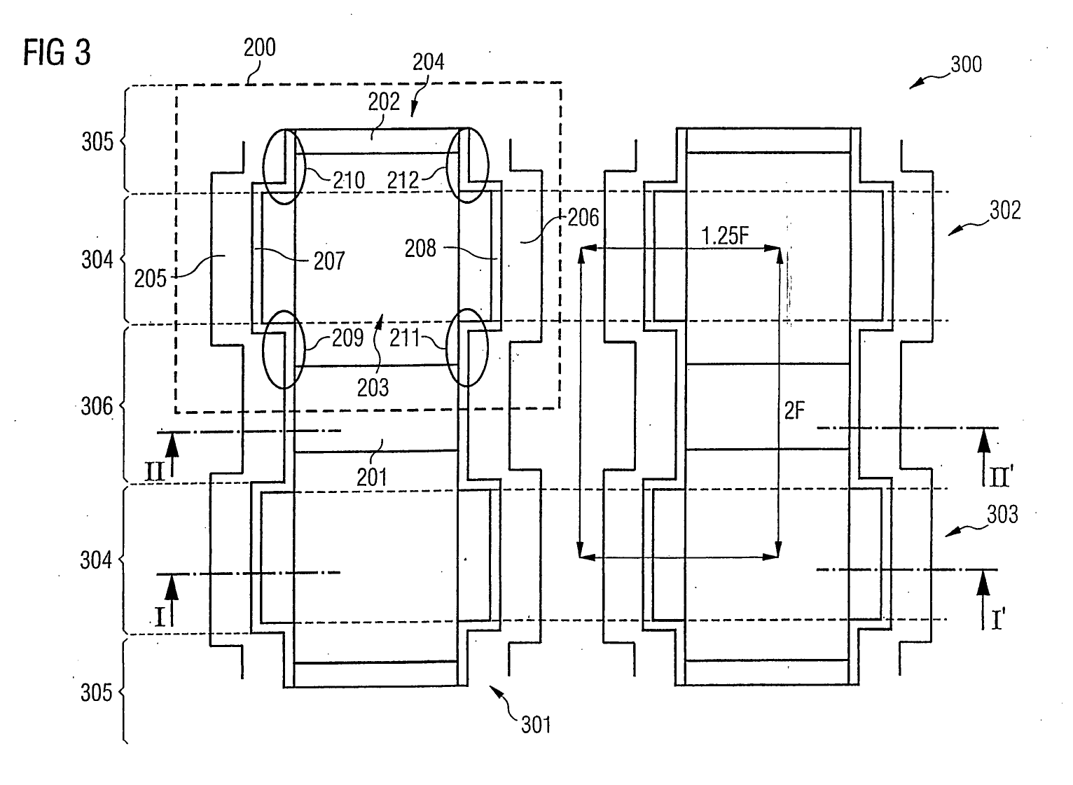

A description is given below, referring to FIG. 3, of a fin field effect transistor memory cell arrangement 300 in accordance with a preferred exemplary embodiment of the invention.

FIG. 3 is a layout view. In FIG. 3, four fin-FET memory cells of the type shown in FIG. 2 are connected up to one another to form a fin-FET memory cell arrangement 300. Furthermore, dimension specifications in F are specified in FIG. 3, where F is the minimum feature size that can be achieved in a technology generation. As is shown in FIG. 3, the memory cells 200, 301 to 303 are arranged in matrix-type fashion, a common first word line 205 and a common second word line 206 being provided in each case for a respective column of memory cells. Furthermore, a common control gate line 304 and also common first and second bit lines 305, 306 are provided for a respective row of memory cells.

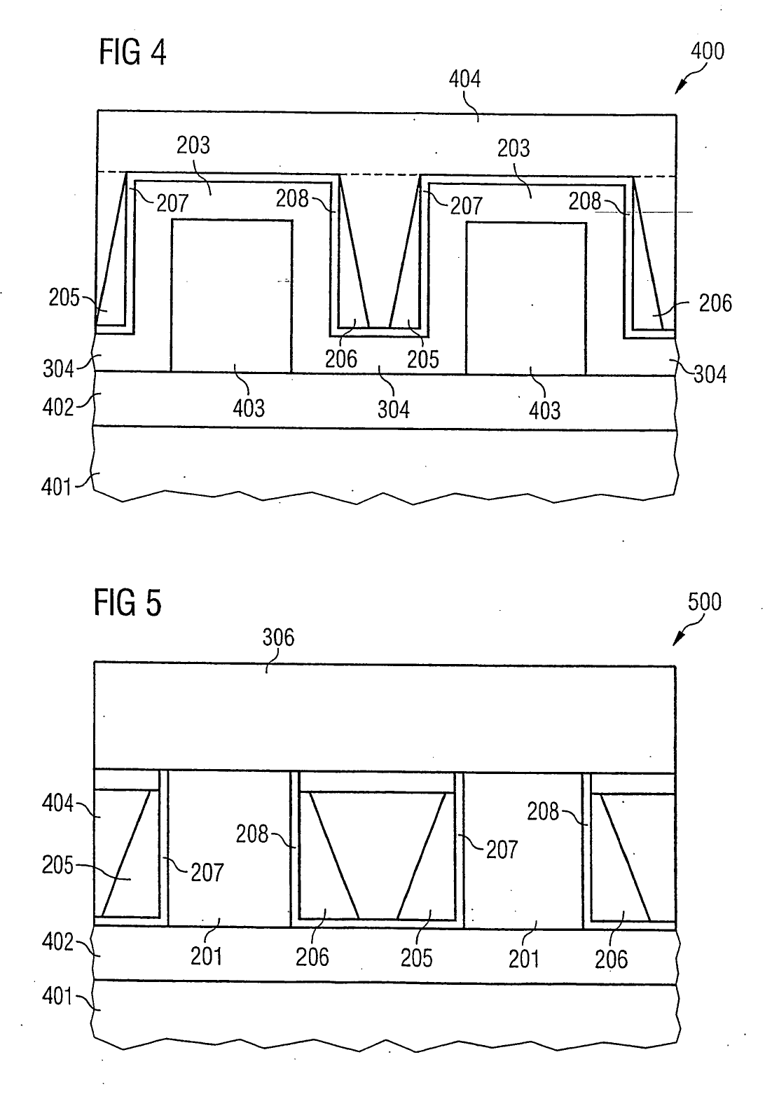

A description is given below, referring to FIG. 4, of a first cross-sectional view 400 of the layout of the fin-FET memory cell arrangement 300 shown in FIG. 3. The first cross-sectional view 400 is taken along a section line I-I′ shown in FIG. 3.

The first cross-sectional view 400 shows that the fin-FET memory cell arrangement 300 is formed on a silicon oxide layer 402, which is in turn arranged on a silicon substrate 401. Furthermore, FIG. 4 shows the channel region 403 of the silicon fin 204. A silicon nitride layer 404 is applied on the layer sequence shown in FIG. 4, said silicon nitride layer being planarized. As is furthermore shown in FIG. 4, the word lines 205, 206 have an approximately triangular cross section in accordance with the exemplary embodiment described. As shown in FIG. 4, the ONO regions 207, 208 are formed as a contiguous ONO layer sequence. Since an ONO layer sequence is electrically insulating, electrical charge carriers possibly introduced in it are impeded from moving along the ONO layer sequence, so that the electrical charge carriers that contain the memory information and are introduced in the ONO layer sequence are protected from smearing out or flowing away.

A description is given below, referring to FIG. 5, of a second cross-sectional view 500 of the fin-FET memory cell arrangement 300 from FIG. 3, taken along a section line II-II′ shown in FIG. 3.

As shown in FIG. 5, the cross section of the first and second word lines 205, 206 along the section line II-II′ is likewise essentially triangular (or slightly trapezoidal), but with a different cross-sectional area than in the first cross-sectional view 400.

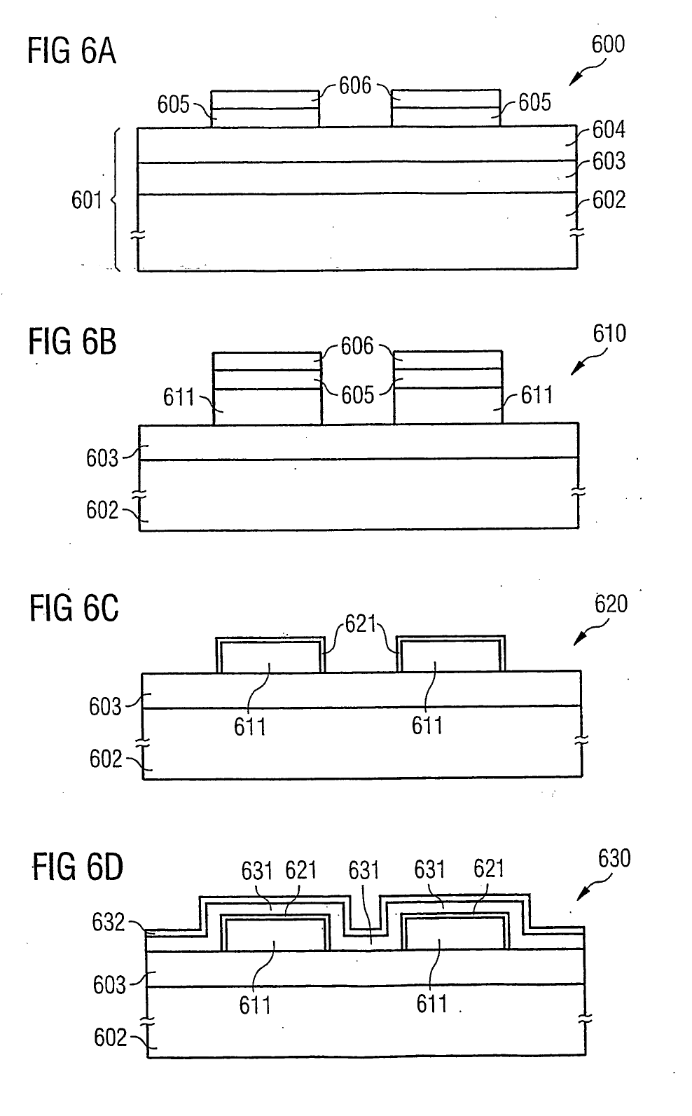

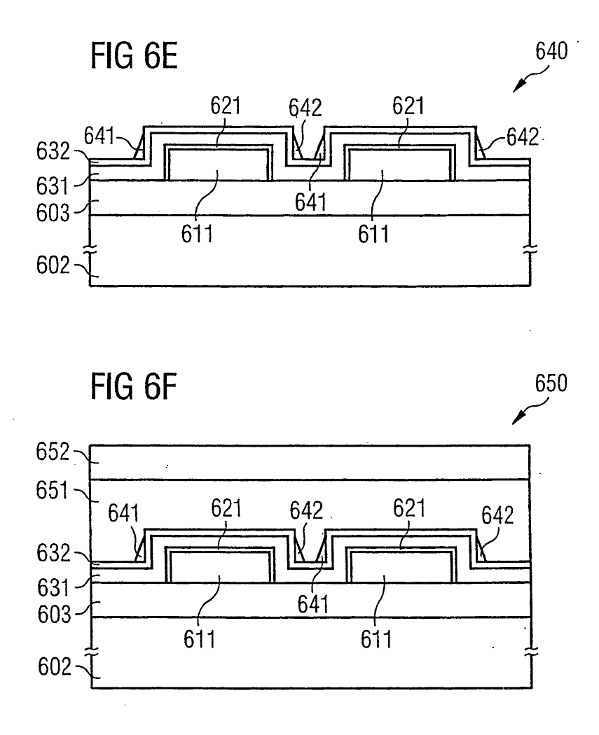

A description is given below, referring to FIG. 6A to FIG. 6F, of a method for the production of a fin-FET memory cell arrangement in accordance with a preferred exemplary embodiment of the invention.

In order to obtain the layer sequence 600 shown in FIG. 6A, firstly an SOI wafer 601 is provided. The latter is formed from a first silicon layer 602, a silicon oxide layer 603 formed on the first silicon layer 602, and from a second silicon layer 604 formed on the silicon oxide layer 603. A TEOS hard mask 605 (tetraethyl orthosilicate) is formed on the layer sequence thus obtained. A photoresist layer 606 is formed on the layer sequence thus obtained and is patterned together with the TEOS layer sequence 605 using a lithography and an etching method such that silicon fins can be produced from the second silicon layer 604 in a subsequent method step.

In order to obtain the layer sequence 610 shown in FIG. 6B, the layer sequence 600 is subjected to an etching method, thereby obtaining silicon fins 611 in accordance with the mask defined by means of the TEOS hard mask 605 and the photoresist 606.

In order to obtain the layer sequence 620 shown in FIG. 6C, the photoresist 606 and the TEOS hard mask 605 are removed. The layer sequence thus obtained may furthermore be subjected to a rounding oxidation method or an etching-back method. Afterward, using a thermal oxidation method, a gate insulating layer 621 is formed on uncovered surface regions of the silicon fins 611, thereby forming a channel dielectric (gate insulating layer) for the fin-FET to be formed.

In order to obtain the layer sequence 630 shown in FIG. 6D, in-situ doped polycrystalline silicon material is deposited on the layer sequence 620 and patterned using a TEOS hard mask and a photoresist by means of lithography and an etching method such that this forms a control gate region 631 on the silicon fins 611 covered with thermal silicon oxide material and on uncovered surface regions of the silicon oxide 603. An ONO layer sequence 632 is subsequently formed over the whole area. For this purpose, firstly the layer sequence covered with the polycrystalline silicon material is subjected to a thermal oxidation method, whereby a first silicon oxide layer of the ONO layer sequence 632 is formed from material of the control gate region 631 made of polycrystalline silicon. The first silicon oxide layer of the ONO layer sequence 632 has a thickness of 5 nm. Silicon nitride material with a thickness of 5 nm is subsequently deposited on the layer sequence thus obtained in order to form a silicon nitride layer as trapping layer of the ONO layer sequence 632. A second silicon oxide layer of the ONO layer sequence 632 with a thickness of 5 nm is subsequently deposited in a high-temperature method.

In order to obtain the layer sequence 640 shown in FIG. 6E, firstly in-situ doped polycrystalline silicon material is deposited on the layer sequence 630. A spacer etching is subsequently carried out in order to form first and second word lines 641, 642. The spacer etching is carried out such that the word lines 641, 642 are arranged somewhat deeper, so that a contact hole etching that is subsequently to be carried out is less critical. The silicon fin 611 should be somewhat higher in the vertical direction in accordance with FIG. 6E than the control gate region 631 on the silicon fin 611, so that the spacer is removed at the control gate region 631 and the word lines 641, 642 are nevertheless formed.

In order to obtain the memory cell 650 shown in FIG. 6F, firstly an additional silicon nitride layer 651 is deposited over the whole area, and a spacer etching is carried out in order to form an implantation mask for bit lines. The bit lines are subsequently implanted (not shown). The layer sequence thus obtained is covered with an additional silicon oxide layer 652. An offset contact whole etching is subsequently carried out in the region of the bit lines, of the control gate 631 and of the word lines 641, 642.

What is claimed is:

1. A fin field effect transistor memory cell, comprising:
a first and a second source/drain region;
a gate region;
a semiconductor fin having a channel region between the first and the second source/drain region;
a charge storage layer configured as a trapping layer arranged at least partly on the gate region; and
a word line region on at least one part of the charge storage layer;
wherein the charge storage layer is set up such that electrical charge carriers can be selectively introduced into the charge storage layer or be removed therefrom by applying predetermined electrical potentials to the fin field effect transistor memory cell.

2. The memory cell as claimed in claim 1, wherein the word line region is divided into a first word line partial region and into a second word line partial region such that electrical charge carriers can in each case be introduced into a boundary region between the first word line partial region and the charge storage layer and into a boundary region between the second word line partial region and the charge storage layer or be removed therefrom.

3. The memory cell as claimed in claim 2, wherein the first and second word line partial regions are arranged at two opposite lateral sections of the gate region.

4. The memory cell as claimed in claim 1, wherein the charge storage layer comprises a silicon oxide/silicon nitride/silicon oxide layer sequence, aluminum oxide, yttrium oxide, lanthanum oxide, hafnium oxide, amorphous silicon, tantalum oxide, titanium oxide, zirconium oxide, and/or an aluminate.

5. The memory cell as claimed in claim 1, wherein the gate region surrounds the semiconductor fin in an essentially U-shaped manner.

6. The memory cell as claimed in claim 1, wherein the height of the semiconductor fin is chosen to achieve a predetermined value for a read current for reading out information stored in the memory cell.

7. The memory cell as claimed in claim 1, further comprising a first bit line region coupled to the first source/drain region and a second bit line region coupled to the second source/drain region.

8. The memory cell as claimed in claim 7, set up such that, by means of applying predetermined electrical potentials to the gate region, to the word line region and to at least one bit line region, charge carriers can selectively be introduced into the charge storage layer by means of injection of hot charge carriers or be removed therefrom.

9. A fin field effect transistor memory cell arrangement, comprising a plurality of fin field effect transistor memory cells as claimed in claim 1.

10. The memory cell arrangement as claimed in claim 9, wherein the fin field effect transistor memory cells are arranged essentially in matrix-type fashion.

11. The memory cell arrangement as claimed in claim 9, wherein memory cells arranged along a first direction have common word line regions.

12. The memory cell arrangement as claimed in claim 11, wherein memory cells arranged along a second direction have common bit line regions.

13. The memory cell arrangement as claimed in claim 12, wherein the first and second directions run essentially orthogonally with respect to one another.

14. The memory cell arrangement as claimed in claim 9, wherein the lateral extent of a word line region is smaller in a section in which it crosses a gate region than in a section free of a crossing with a gate region.

15. A method for producing a fin field effect transistor memory cell, comprising the steps of:
forming a first and a second source/drain region;
forming a gate region;
forming a semiconductor fin having a channel region between the first and the second source/drain regions;
forming a charge storage layer configured as a trapping layer, which is arranged at least partly on the gate region; and
forming a word line region on at least one part of the charge storage layer,
wherein the charge storage layer is set up such that electrical charge carriers can be selectively introduced into the charge storage layer or be removed therefrom by applying predetermined electrical potentials to the fin field effect transistor memory cell.

16. The method as claimed in claim 15, further comprising the step of dividing the word line region into a first word line partial region and into a second word line partial region such that electrical charge carriers can in each case be introduced into a boundary region between the first word line partial region and the charge storage layer and into a boundary region between the second word line partial region and the charge storage layer or be removed therefrom.

17. The method as claimed in claim 16, wherein the first and second word line partial regions are arranged at two opposite lateral sections of the gate region.

18. The method as claimed in claim 15, wherein the charge storage layer comprises a silicon oxide/silicon nitride/silicon oxide layer sequence, aluminum oxide, yttrium oxide, lanthanum oxide, hafnium oxide, amorphous silicon, tantalum oxide, titanium oxide, zirconium oxide, and/or an aluminate.

19. The method as claimed in claim 15, wherein the gate region is formed such that it surrounds the semiconductor fin in an essentially U-shaped manner.

20. The method as claimed in claim 15, further comprising the step of choosing the height of the semiconductor fin to achieve a predetermined value for a read current for reading out information stored in the memory cell.

21. The method as claimed in claim 15, further comprising the step of producing a first bit line region coupled to the first source/drain region and a second bit line region coupled to the second source/drain region.

22. The method as claimed in claim 21, wherein the mempory cell is produced such that, by means of applying predetermined electrical potentials to the gate region, to the word line region and to at least one bit line region, charge carriers can selectively be introduced into the charge storage layer by means of injection of hot charge carriers or be removed therefrom.

23. A system for producing a fin field effect transistor memory cell, comprising:
means for forming a first and a second source/drain region;
means for forming a gate region;
means for forming a semiconductor fin having a channel region between the first and the second source/drain regions;
means for forming a charge storage layer configured as a trapping layer, which is arranged at least partly on the gate region; and
means for forming a word line region on at least one part of the charge storage layer,
wherein the charge storage layer is set up such that electrical charge carriers can be selectively introduced into the charge storage layer or be removed therefrom by applying predetermined electrical potentials to the fin field effect transistor memory cell.

24. The system as claimed in claim 23, further comprising means for dividing the word line region into a first word line partial region and into a second word line partial region such that electrical charge carriers can in each case be introduced into a boundary region between the first word line partial region and the charge storage layer and into a boundary region between the second word line partial region and the charge storage layer or be removed therefrom.

25. The system as claimed in claim 23, further comprising means for producing a first bit line region coupled to the first source/drain region and a second bit line region coupled to the second source/drain region.
